(19) United States
(12) Patent Application Publication
(10) Pub. No.: US 2025/0112443 A1
(43) Pub. Date: Apr. 3, 2025

(54) SEMICONDUCTOR DEVICE

(71) Applicant: Epistar Corporation, Hsinchu (TW)

(72) Inventors: Po-Chou PAN, Hsinchu (TW); Chen OU, Hsinchu (TW); Shih-Chang LEE, Hsinchu (TW); Wei-Chih PENG, Hsinchu (TW); Yao-Ru CHANG, Hsinchu (TW); Hao-Chun LIANG, Hsinchu (TW)

(21) Appl. No.: 18/899,846

(22) Filed: Sep. 27, 2024

(30) Foreign Application Priority Data
Sep. 28, 2023 (TW) 112137303

(51) Int. Cl. H01S 5/11; H01S 5/042

(52) U.S. Cl. CPC H01S 5/11; H01S 5/04256

(57) ABSTRACT

An embodiment of the present disclosure provides a semiconductor device. The semiconductor device has a first semiconductor structure; a second semiconductor structure on the first semiconductor structure and having a first aluminum content; a plurality of voids in the second semiconductor structure; an active structure between the first semiconductor structure and the second semiconductor structure; and a third semiconductor structure between the active structure and the second semiconductor structure, and having a second aluminum content. The first aluminum content is greater than the second aluminum content.

### BACKGROUND

### Technical Field

The present disclosure relates to a semiconductor device, especially a semiconductor device with a photonics crystal structure.

### Description of the Related Art

Semiconductor Devices are widely used, and the research and development of related materials are also continuously being carried out. For example, III-V semiconductor materials may be applied to various semiconductor devices, such as light-emitting diode (LED), laser diode (LD), photodetectors or solar cells, power device for switches or rectifiers, which can be used in lighting, medical treatment, display, communication, sensing, power supply systems and other applications. With the development of science and technology, there are still many technical research and development needs for semiconductor devices. Although existing semiconductor devices have generally met various needs, they are not satisfactory in all aspects and further improvements are still needed.

### BRIEF SUMMARY

An embodiment of the present disclosure provides a semiconductor device. The semiconductor device has a first semiconductor structure; a second semiconductor structure on the first semiconductor structure and having a first aluminum content; a plurality of voids in the second semiconductor structure; an active structure between the first semiconductor structure and the second semiconductor structure; and a third semiconductor structure between the active structure and the second semiconductor structure, and comprising a second aluminum content. The first aluminum content is greater than the second aluminum content.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIG. 1 is a schematic diagram of a cross-sectional view of a semiconductor device in accordance with some embodiments.

FIG. 2 is a schematic diagram of a top view of a photonics crystal structure of a semiconductor device in accordance with some embodiments.

FIG. 3A is a schematic diagram of an enlarged cross-sectional view of the area G in FIG. 1.

FIGS. 3B and 3C are schematic diagrams of a partial enlarged cross-sectional view of a semiconductor device in accordance with some embodiments.

FIG. 4 is a schematic diagram of a partial enlarged cross-sectional view of a semiconductor device in accordance with some embodiments.

FIG. 5 is a schematic diagram of a cross-sectional view of a semiconductor device in accordance with some embodiments.

FIG. 6 is a schematic diagram of a cross-sectional view of a semiconductor device in accordance with some embodiments.

FIG. 7A is a schematic diagram of a cross-sectional view of a semiconductor device in accordance with some embodiments.

FIGS. 7B and 7C are respectively schematic diagrams of a top view of a semiconductor device in accordance with some embodiments.

FIG. 8 is a schematic diagram of a cross-sectional view of a semiconductor device in accordance with some embodiments.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to limit the embodiments. For example, the formation of a first element over or on a second element in the description that follows may include embodiments in which the first element and second element are formed in direct contact, and may also include embodiments in which additional features may be formed between the first element and second element, such that the first element and second element may not be in direct contact.

Further, spatially relative terms, such as “below,” “above,” “on” may be used herein for ease of description the relationship between one element or feature and another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless otherwise defined in the embodiments of this disclosure, all terms (including technical and scientific terms) used herein have the same meanings as commonly understood by person of ordinary skill in the art to which this disclosure belongs. It should be understood that these terms, such as those defined in commonly used dictionaries, should be interpreted to have meanings consistent with the relevant technology and the background or context of the present disclosure, and should not be interpreted in an idealized or overly formal manner.

The composition of each layer, the type of dopant and defects included in the semiconductor device of the present disclosure can be analyzed by any suitable method, such as secondary ion mass spectrometer (SIMS), transmission electron microscopy (TEM) or scanning electron microscope (SEM). The thickness of each layer can also be analyzed by any suitable method, such as transmission electron microscope or scanning electron microscope.

The semiconductor device of the present disclosure may include a light-emitting chips, such as a light-emitting diode or a laser diode, a light-absorbing chip, such as a photodetector or a solar cell, or a non-light-emitting chip, such as a switch or a power rectifier element. The laser diode can be a surface-emitting laser diode (VCSEL) or a photonic crystal surface-emitting laser (PCSEL). In the various schematic diagrams and illustrative embodiments described below, similar reference numbers are used to represent similar elements.

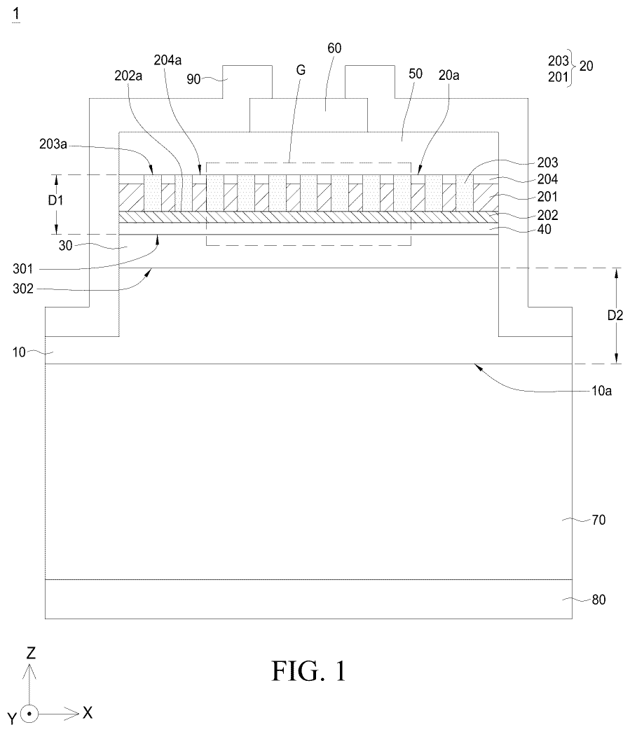

FIG. 1 shows a cross-sectional view of a semiconductor device 1 in accordance with some embodiments. The semiconductor device 1 includes a first semiconductor structure 10, a second semiconductor structure 201 and the third semiconductor structure 202. The semiconductor device 1 also includes an active structure 30 located between the first semiconductor structure 10 and the second semiconductor structure 201, and a plurality of voids 203 located in the second semiconductor structure 201. One of the plurality of voids 203 includes an opening 203a away from the active structure 30. The third semiconductor structure 202 is located between the active structure 30 and the second semiconductor structure 201. In this embodiment, the second semiconductor structure 201 and a plurality of voids 203 is formed and defined as a photonics crystal structure 20, and the active structure 30 is located between the first semiconductor structure 10 and the photonics crystal structure 20. The second semiconductor structure 201 and a plurality of voids 203 can jointly form a resonant cavity, so that the light emitted by the active structure 30 oscillates in the photonic crystal structure 20, thereby allowing the light of a specific wavelength to satisfy the conservation of energy and conservation of momentum to emit out from the semiconductor device 1 along a stacking direction of the first semiconductor structure 10 and the third semiconductor structure 201, such as the Z direction shown in FIG. 1.

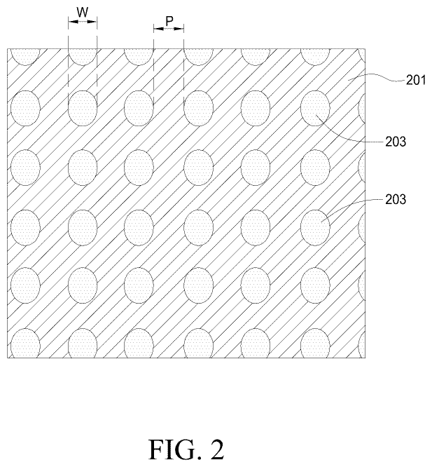

From a top view of the photonics crystal structure 20 as shown in FIG. 2, the arrangement of the plurality of voids 203 is periodic, such as a two-dimensional array arrangement or other periodic arrangements. The top view shape of one of the plurality of voids 203 is circular and includes a diameter W between 80 nm and 300 nm, and the shortest gap P between two adjacent voids 203 is between 80 nm and 300 nm. For example, the diameter W is between 130 nm and 180 nm, and the gap P is between 100 nm and 160 nm. In other embodiments, the top-view shape of one of the plurality of voids 203 may be a triangle, a hexagon, or other shapes. The photonics crystal structure 20 has a filling factor (FF) between 0.1 and 0.6, such as 0.1˜0.25, or 0.2˜0.5. When the filling factor is between 0.1 and 0.25, the semiconductor device 1 can emit a laser light. The above filling factor is defined as

$$\frac{{π ( \frac{W}{2} )}^{2}}{{( W + P )}^{2}} .$$

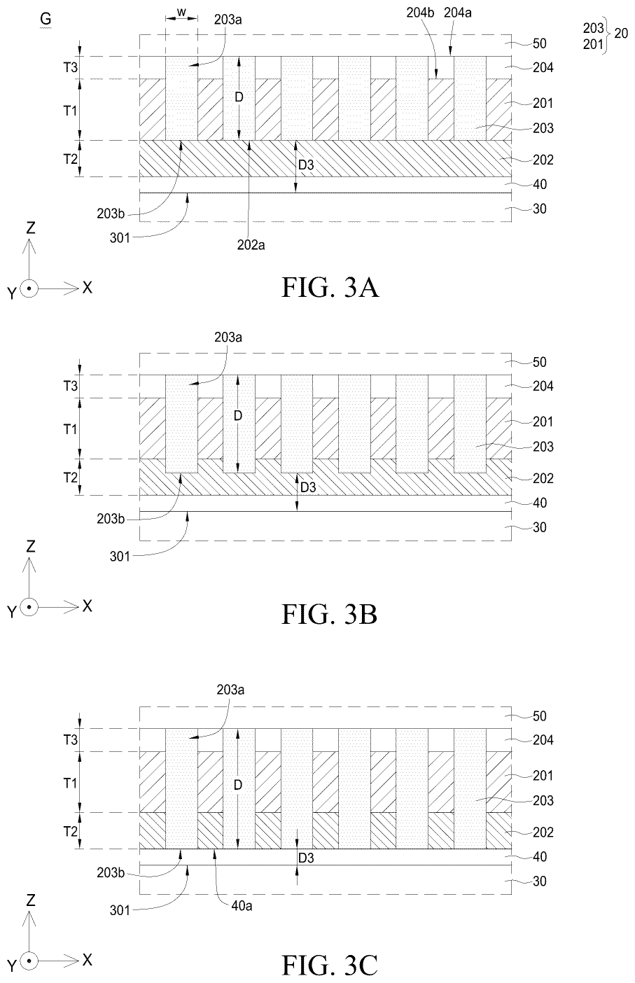

In this embodiment, the plurality of voids 203 is formed through an etching process. Specifically, after the epitaxial growth of the first semiconductor structure 10, the active structure 30, the third semiconductor structure 202 and the second semiconductor structure 201, a wet etching or dry etching process (such as inductively coupled plasma (ICP) etching method) can be carried out to remove part of the second semiconductor structure 201 (as shown in FIG. 3A), or to remove a part of the second semiconductor structure 201 and a part of the third semiconductor structure 202 (as shown in FIG. 3B or 3C) to form the plurality of voids 203. In other words, the plurality of voids penetrates the second semiconductor structure 201 and a part of the third semiconductor structure 202. The plurality of voids 203 can be filled with epitaxial materials, dielectric materials, or not deliberately filled with any materials (that is, air fills in the plurality of voids 203). In some embodiments, the plurality of voids 203 can be filled with silicon oxide or silicon nitride.

In this embodiment, the second semiconductor structure 201 and the third semiconductor structure 202 have different etching rates. Specifically, the second semiconductor structure 201 has a first etching rate E1, the third semiconductor structure 202 has a second etching rate E2, and the first etching rate E1 is greater than the second etching rate E2. The first etching rate E1 is 1.5 to 10 times greater than the second etching rate E2. For example, the ratio between the first etching rate E1 and the second etching rate E2 (E1/E2) is 1.8˜8, 2˜5, or 2˜3. In other words, when an etching process is performed to form the plurality of voids 203, the third semiconductor structure 202 can be served as an etching stop layer to control the depth D of each void 203 and reduce the risk of process errors. In some embodiments, by arranging the third semiconductor structure 202 on the active structure 30, the resonance cavity formed by the second semiconductor structure 201 and the plurality of voids 203 can be as close as possible to the active structure 30, thereby increasing the resonance effect. In some embodiments, the depth D of the plurality of voids 203 can be controlled by adjusting the etching time.

In some embodiments, the plurality of voids 203 is formed by dry etching process, while the etching rate of the second semiconductor structure 201 is 7˜12 nm/s, and the etching rate of the third semiconductor structure 202 is 2˜5 nm/s.

In some embodiments, the second semiconductor structure 201 and the third semiconductor structure 202 include different materials. For example, the second semiconductor structure 201 and the third semiconductor structure 202 have different aluminum contents. More specifically, the second semiconductor structure has a first aluminum content, and the third semiconductor structure has a second aluminum content. The first aluminum content of the second semiconductor structure 201 is greater than the second aluminum content of the third semiconductor structure 202. In some embodiments, the second semiconductor structure 201 includes aluminum and the third semiconductor structure 202 does not contain aluminum.

In some embodiments, the semiconductor device 1 optionally includes a contact structure 204 located on the second semiconductor structure 201, and the plurality of voids 203 penetrates the contact structure 204. The semiconductor device 1 can also optionally include a fourth semiconductor structure 40 and a conductive layer 50. The fourth semiconductor structure 40 is located between the active structure 30 and the photonics crystal structure 20. The conductive layer 50 is located on the photonics crystal structure 20, and the contact structure 204 is located between the second semiconductor structure 201 and the conductive layer 50. In this embodiment, the semiconductor device 1 further includes a first electrode structure 60, a second electrode structure 80 and a base 70 located between the first electrode structure 60 and the second electrode structure 80. The first electrode structure 60 is located on the photonics crystal structure 20, and the base 70 is located between the first semiconductor structure 10 and the second electrode structure 80. The conductive layer 50 is located between the first electrode structure 60 and the photonics crystal structure 20. The first semiconductor structure 10, active structure 30 and photonics crystal structure 20 are located between the first electrode structure 60 and the second electrode structure 80, so that the semiconductor device 1 is a vertical structure. The semiconductor device 1 may also optionally include a protective layer 90 covering the first semiconductor structure 10, the photonics crystal structure 20 and the active structure 30.

In this embodiment, the semiconductor device 1 includes an asymmetric epitaxial structure. More specifically, the active structure 30 has a first surface 301 and a second surface 302 opposite to the first surface 301. The first surface 301 is closer to the photonics crystal structure 20 than the second surface 302 to the photonics crystal structure 20. The contact structure 204 includes a third surface 204a far away from the active structure 30, and the first semiconductor structure 10 includes a bottom surface 10a away from active structure 30. As shown in FIG. 1, there is a first distance D1 between the first surface 301 of the active structure 30 and the third surface 204a of the contact structure 204, and there is a second distance D2 between the second surface 302 of the active structure 30 and the bottom surface 10a of the first semiconductor structure 10. The second distance D2 is different from first distance D1 (D1+D2), and this satisfies the definition of above-mentioned “asymmetric epitaxial structure”. In this embodiment, D2/D1 is 3˜6. In the embodiment, the first semiconductor structure 10 includes a thickness which is equal to the second distance D2. The conductive layer 50 is disposed on a side adjacent to the first surface 301 of the active structure 30, and the overall thickness of the epitaxial structure (for example, the second semiconductor structure 201, the third semiconductor structure 202 and/or the contact structure 204) on the side is thinner than the epitaxial structure (such as the first semiconductor structure 10) on a side adjacent to the second surface 302 of the active structure 30, thereby helping the current diffusion of the active structure 30 on the side adjacent to the first surface 301. In this embodiment, the conductive layer 50 is disposed on the photonics crystal structure 20. The first distance D1 is between 210 nm and 800 nm. The second distance D2 is between 1000 nm and 4000 nm, such as 2000 nm˜2500 nm.

FIG. 3A is a schematic diagram of an enlarged cross-sectional view of the area G in FIG. 1. The second semiconductor structure 201 has a first thickness T1, the third semiconductor structure 202 has a second thickness T2, and the contact structure 204 has a third thickness T3. One of the plurality of voids 203 has a depth D and the diameter W. The depth D is 200 nm to 650 nm to produce optical coupling effect. In this embodiment, the depth D is approximately equal to the sum of the first thickness T1 and the third thickness T3. That is, D=T1+T3. For example, the depth D is between 300 nm and 400 nm. In other words, one of the plurality of voids 203 extends from the third surface 204a of the contact structure 204 to the upper surface 202a of the third semiconductor structure 202. More specifically, one of the plurality of voids 203 penetrates the contact structure 204 and the second semiconductor structure 201, and one of the plurality of voids 203 has a bottom 203b approximately aligned with the interface between the second semiconductor structure 201 and the third semiconductor structure 202. The first surface 301 of the active structure 30 faces the upper surface 202a of the third semiconductor structure 202, and there is a third distance D3 of 10 nm to 150 nm between the bottom 203b and the first surface 301. It is beneficial to make the light emitted by the active structure 30 couple the photonics crystal 20 and manipulate light characteristics in order to generate a laser light. The first thickness T1 is greater than the second thickness T2, and T1/T2 is 5˜20. In this embodiment, the first thickness T1 is between 250 nm and 500 nm, the second thickness T2 is between 15 nm and 150 nm, and the third thickness T3 is between 30 nm and 100 nm.

FIG. 3B is a schematic diagram of a partial enlarged cross-sectional view of a semiconductor device in accordance with some embodiments. In this embodiment, one of the plurality of voids 203 further penetrates a part of the third semiconductor structure 202. That is, the bottom 203b is located in the third semiconductor structure 202. In other words, in addition to the contact structure 204 and the second semiconductor structure 201, a part of the third semiconductor structure 202 is also removed. In this embodiment, T1+T3<D<T1+T2+T3.

FIG. 3C is a schematic diagram of a partial enlarged cross-sectional view of a semiconductor device in accordance with some embodiments. In this embodiment, one of the plurality of voids 203 penetrates the contact structure 204, the second semiconductor structure 201 and the third semiconductor structure 202 and extends to the upper surface 40a of the fourth semiconductor structure 40 That is, the bottom 203b approximately aligns with the interface of the third semiconductor structure 202 and the fourth semiconductor structure 40. In other words, in addition to the contact structure 204 and the second semiconductor structure 201, the third semiconductor structure 202 is also removed. In this embodiment, D=T1+T2+T3. The plurality of voids 203 is devoid of penetrating the fourth semiconductor structure 40.

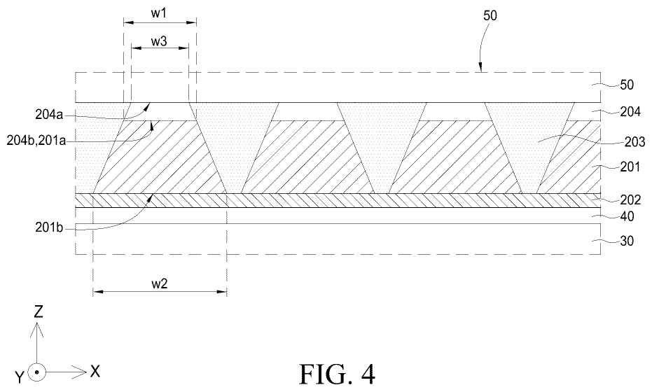

FIG. 4 is a schematic diagram of a partial enlarged cross-sectional view of a semiconductor device in accordance with some embodiments. In this embodiment, the shape of the second semiconductor structure 201 and/or the contact structure 204 is/are generally trapezoidal. That is, the width(s) of the second semiconductor structure 201 and/or the contact structure 204 gradually decrease(s) away from the active structure 30, and the width of one of the plurality of voids 203 increases in the direction away from the active structure 30. Specifically, the second semiconductor structure 201 has an upper surface 201a and a lower surface 201b opposite to the upper surface 201a. The upper surface 201a is connected to the contact structure 204 and has a first width w1. The lower surface 201b is connected to the third semiconductor structure 202 and has a second width w2 greater than the first width w1. The contact structure 204 has a fourth surface 204b opposite to the third surface 204a. The third surface 204a of the contact structure 204 is connected to the conductive layer 50 and has a third width w3 smaller than the first width w1. The fourth surface 204b is connected to the second semiconductor structure 201. Therefore, a width of the fourth surface 204b is approximately equal to the first width w1.

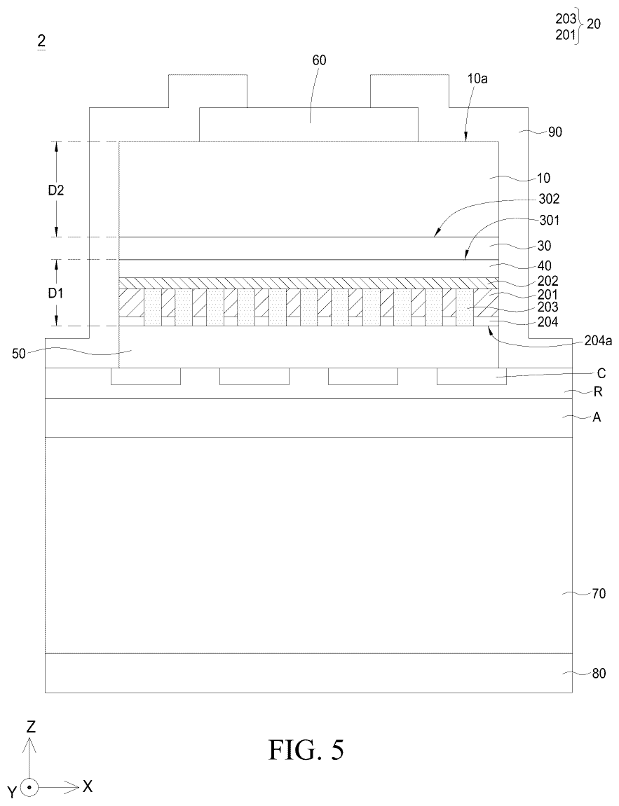

FIG. 5 is a schematic diagram of a cross-sectional view of a semiconductor device 2 in accordance with some embodiments. The elements, the connection between the elements, the thicknesses and the distances between the elements of the semiconductor device 2 in this embodiment are generally similar to that of the above-mentioned semiconductor device 1. The difference between the semiconductor device 2 and the semiconductor device 1 is that, the photonics crystal structure 20 in this embodiment is located between the active structure 30 and the base 70, and the conductive layer 50 is located between the base 70 and the photonics crystal structure 20, and the semiconductor device 2 further includes an adhesive layer A and a reflective layer R. The adhesive layer A is located between the photonics crystal structure 20 and base 70, and the reflective layer R is located between the photonics crystal structure 20 and the adhesive layer A. The adhesive layer A electrically connects to the reflective layer R. The semiconductor device 2 of this embodiment can also optionally include a plurality of blocking structures C located between the photonics crystal structure 20 and the reflective layer R. The plurality of blocking structures C contacts the conductive layer 50 and is able to prevent current from passing through some areas to evenly spread the current. The semiconductor device 2 of this embodiment also has the asymmetric epitaxial structure as mentioned above, and that is D1+D2. In the embodiment, D1<D2. The conductive layer 50 is disposed on a side adjacent to the first surface 301 of the active structure 30, and the overall thickness of the epitaxial structure, such as the second semiconductor structure 201, the third semiconductor structure 202, the fourth structure semiconductor 40 and/or the contact structure 204 of the epitaxial structure on this side, is thinner, thereby the conductive layer 50 can promote the current diffusion under the active structure 30. In this embodiment, a thickness of the conductive layer 50 is 30 nm to 300 nm. If the thickness of the conductive layer 50 is too thin, the conductive layer 50 is not able to present a complete film layer, thereby reducing the conductivity. If the thickness of the conductive layer 50 is too thick, the transmittance of the conductive layer 50 can be reduced and the brightness of the semiconductor device can be affected. The material of the adhesive layer A may be metal, alloy or conductive oxide.

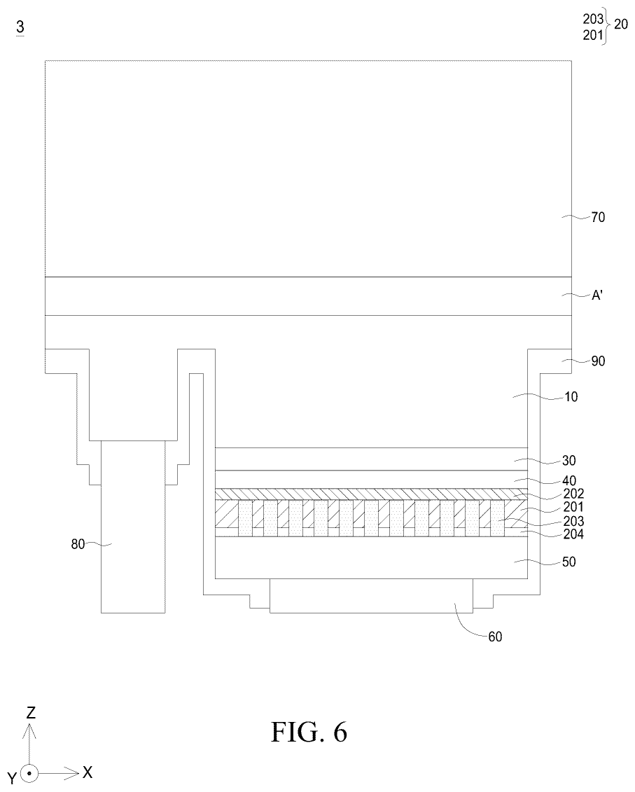

FIG. 6 is a schematic diagram of a cross-sectional view of a semiconductor device 3 in accordance with some embodiments. The elements, the connection between the elements, the thicknesses and the distances between the elements of the semiconductor device 3 in this embodiment are generally similar to that of the above-mentioned semiconductor device 1. The difference between the semiconductor device 3 and the semiconductor device 1 is that, the first electrode structure 60 and the second electrode structure 80 in this embodiment are arranged on the same side of the first semiconductor structure 10. The semiconductor device 3 is a horizontal structure and includes an adhesive layer A′ between the base 70 and the first semiconductor structure 10. In this embodiment, since the light emitted by the active structure 30 can be selectively emitted toward the base 70, the materials of the base 70 and the adhesive layer A′ can be selected to have high transmittance for the light emitted by the active structure 30. For example, the base 70 can be sapphire, and the adhesive layer A′ can be silicon oxide, titanium oxide, silicon nitride, or aluminum oxide.

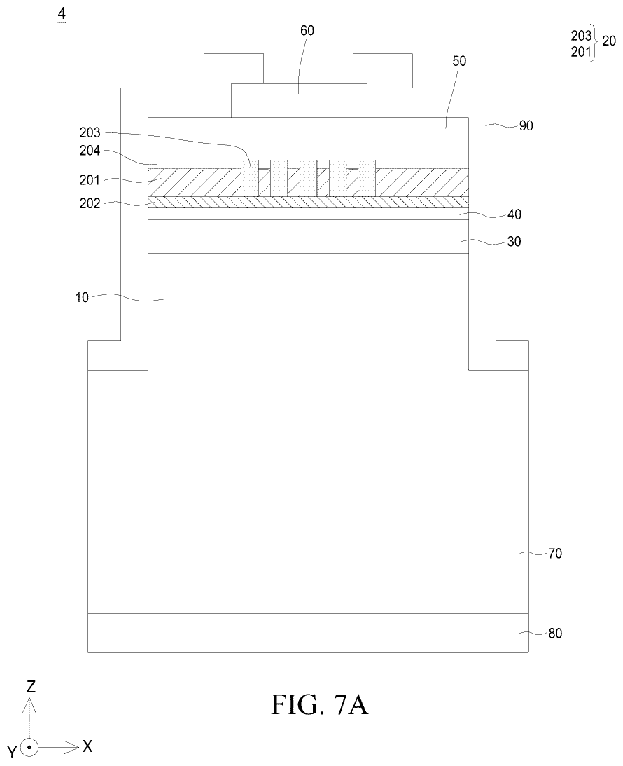

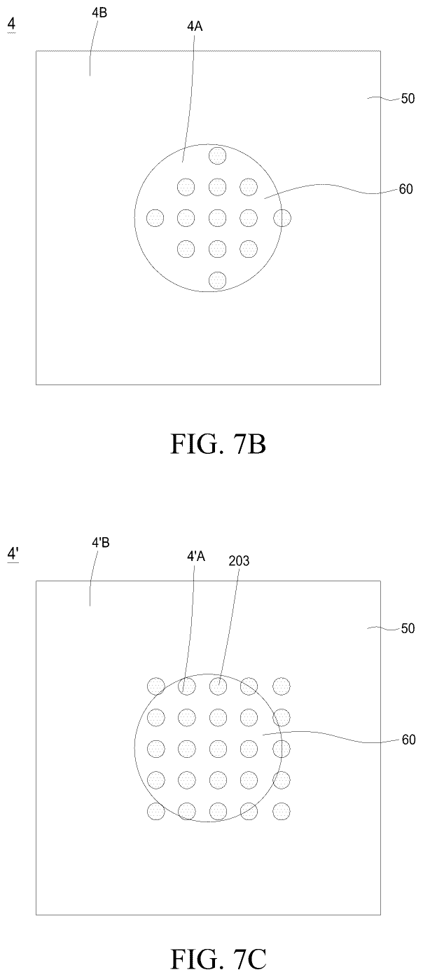

FIG. 7A is a schematic cross-sectional view of a semiconductor device 4 according to an embodiment of the present disclosure. The elements, the connection between the elements, the thicknesses and the distances between the elements of the semiconductor device 4 in this embodiment are generally similar to that of the above-mentioned semiconductor device 1. The difference between the semiconductor device 4 and the semiconductor device 1 is that, the plurality of voids 203 in this embodiment are located at the positions corresponding to the first electrode structure 60, and the plurality of voids 203 and the first electrode structures 60 generally overlap in the vertical direction. FIG. 7B schematic diagrams of a top view of the semiconductor device 4 in accordance with some embodiments, and only some elements are shown in FIG. 7B. The semiconductor device 4 has a central region 4A and an edge region 4B surrounding the central region 4A. The plurality of voids 203 is substantially located in the central region 4A, and there is essentially no void 203 located in the edge region 4B. In this embodiment, the central region 4A substantially corresponds to the position of the first electrode structure 60. In this embodiment, in addition to being disposed below the first electrode structure 60, the plurality of void 203 are also disposed adjacent to the first electrode structure 60. In another embodiment, the plurality of voids 203 is only located under the first electrode structure 60 so the plurality of voids 203 overlaps the first electrode structure 60 in the vertical direction.

FIG. 7C is a schematic top view of a semiconductor device 4′ according to another embodiment of the present disclosure, and only some elements are shown in FIG. 7C. The elements, the connection between the elements, the thicknesses and the distances between the elements of the semiconductor device 4′ in this embodiment are generally similar to that of the above-mentioned semiconductor device 4. The plurality of voids 203 is substantially located in the central region 4′A, and there is essentially no void 203 in the edge region 4′B. The difference between the semiconductor device 4′ and the semiconductor device 4 is that, the plurality of voids 203 is distributed in a rectangular array.

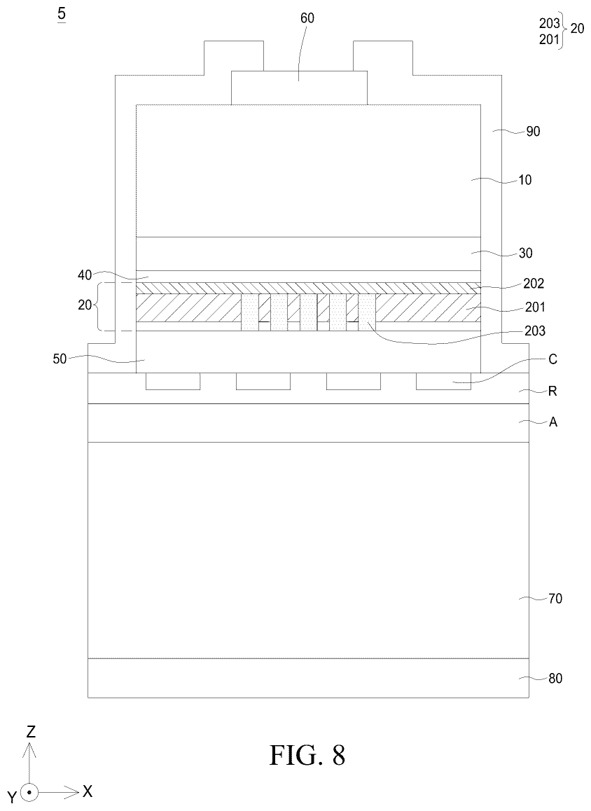

FIG. 8 is a schematic diagram of a cross-sectional view of a semiconductor device 5 in accordance with some embodiments. The elements, the connection between the elements, the thicknesses and the distances between the elements of the semiconductor device 5 in this embodiment are generally similar to that of the above-mentioned semiconductor device 2. The difference between the semiconductor device 5 and the semiconductor device 2 is that, the plurality of voids 203 in this embodiment are located at the positions corresponding to the first electrode structure 60, and the plurality of voids 203 and the first electrode structures 60 generally overlap in the vertical direction.

The first semiconductor structure 10 and the fourth semiconductor structure 40 may have different conductive types. The second semiconductor structure 201, the third semiconductor structure 202, the contact structure 204 and the fourth semiconductor structure 40 have the same conductive type, which is different from the conductive type of the first semiconductor structure 10. For example, the first semiconductor structure 10 is n-type, and the second semiconductor structure 201, the third semiconductor structure 202, the contact structure 204, and the fourth semiconductor structure 40 are p-type. In some embodiments, the first semiconductor structure 10 is p-type, and the second semiconductor structure 201, the third semiconductor structure 202, the contact structure 40, and the fourth semiconductor structure 40 are n-type.

The first semiconductor structure 10 and the fourth semiconductor structure 40 can respectively provide electrons and holes or holes and electrons. The first semiconductor structure 10 has a first dopant, and the fourth semiconductor structure 40 has a second dopant different from the first dopant, and therefore the first semiconductor structure 10 and the fourth semiconductor structure 40 have different conductive types. The first dopant and the second dopant may respectively be carbon (C), zinc (Zn), silicon (Si), germanium (Ge), tin (Sn), selenium (Se), magnesium (Mg) or tellurium (Te). In this embodiment, the first semiconductor structure 10 is n-type, and the first dopant is tellurium (Te) or silicon (Si). The fourth semiconductor structure 40 is p-type, and the first dopant is magnesium (Mg) or zinc (Zn). The doping concentration of the first semiconductor structure 10 and the fourth semiconductor structure 40 is respectively about 5×10¹⁷/cm³ to 1×10²⁰/cm³. In this embodiment, the second dopant in the fourth semiconductor structure 40 has variable doping concentration depending on the distances to the active structure 30. For example, when the position in the fourth semiconductor structure 40 is closer to the active structure 3, the doping concentration of the second dopant is lower. It can prevent the second dopant from entering the active structure 30 and deteriorating the luminescence characteristics of the semiconductor device.

In the embodiment, the second semiconductor structure 201, the third semiconductor structure 202 and the contact structure 204 also have the second dopant, and the concentration of the second dopant of the contact structure 204 is greater than that of the second semiconductor structure 201. The concentration of the second dopant of the second semiconductor structure 201 is greater than that of the third semiconductor structure 202. It can prevent the second dopant from entering the active structure 30 and deteriorating the luminescence characteristics of the semiconductor device.

The first semiconductor structure 10, the second semiconductor structure 201, the third semiconductor structure 202, the contact structure 204, the fourth semiconductor structure 40 and the active structure 30 may respectively include III-V semiconductor materials. The III-V semiconductor materials may include elements of Al, Ga, As, P or In. In some embodiments, the first semiconductor structure 10, the second semiconductor structure 201, the third semiconductor structure 202, the contact structure 204, the fourth semiconductor structure 40 and the active structure 30 do not contain nitrogen (N). Specifically, the III-V semiconductor materials can be binary compound semiconductors (such as GaAs, GaP or InP), ternary compound semiconductors (such as InGaAs, AlInAs, AlGaAs, InGaP or AlInP) or quaternary compound semiconductors (such as AlGaInAs, AlGaInP, InGaAsP, InGaAsN or AlGaAsP). In some embodiments, the active structure 30 is a ternary compound semiconductor (such as InGaAs, AlGaAs, InGaP or AlInP) or a quaternary compound semiconductor (such as AlGaInAs, AlGaInP, InGaAsP or AlGaAsP). In this embodiment, the second semiconductor structure 201 and the fourth semiconductor structure 40 have the same material, such as aluminum indium arsenide (AlInAs), and the third semiconductor structure 202 and the second semiconductor structure 201 have different materials. In some embodiments, the material of the second semiconductor structure 201 is aluminum indium arsenide (AlInAs), the material of the third semiconductor structure 202 is indium phosphide (InP).

The semiconductor devices 1, 2, 3, 4, 4′, 5 may include double heterostructure (DH), double-side double heterostructure (DDH) or multiple quantum wells (MQW) structure. When the semiconductor devices 1, 4, and 4′ are light-emitting devices, the active structure 30 can emit a light toward the direction of the photonics crystal structure 20. When the semiconductor devices 2, 3, and 5 are light-emitting devices, the active structure 30 can emit a light toward the direction of the first semiconductor structure 10. The light includes visible light or invisible light. The wavelength of light emitted by semiconductor devices 1, 2, 3, 4, 4′ and 5 is determined by the material of active structure 30. The material of the active structure 30 may include elements of Al, Ga, In, As or/and P, such as InGaAs, AlGaAsP, GaAsP, InGaAsP, AlGaAs, AlGaInAs, InGaP or AlGaInP. For example, the active structure 30 can emit infrared light with a peak wavelength of 700 to 2200 nm, red light with a peak wavelength of 610 nm to 700 nm, or yellow light with a peak wavelength of 530 nm to 600 nm. In this embodiment, the active structure 30 emits near-infrared light with a peak wavelength of 1000 nm to 2000 nm.

In this embodiment, the crystal structure of material of each layer in the epitaxial structure is cubic and has a zincblende structure. In some embodiments, there is no polarization in each layer of the epitaxial structure. That is, the polarization vector of each layer is substantially zero.

The conductive layer 50 can be transparent to the light emitted by the active structure 30, and the material of the conductive structure 50 includes indium tin oxide (ITO), indium oxide (InO), tin oxide (SnO), cadmium tin oxide (CTO), antimony oxide Tin (ATO), aluminum zinc oxide (AZO), zinc tin oxide (ZTO), gallium zinc oxide (GZO), zinc oxide (ZnO), indium cerium oxide (ICO), indium tungsten oxide (IWO), indium titanium oxide (ITiO), indium zinc oxide (IZO) or indium gallium oxide.

The base 70 includes conductive material or insulating material. The base 70 of semiconductor devices 1, 2, 4, 4′, and 5 includes conductive material such as gallium arsenide (GaAs), indium phosphide (InP), silicon carbide (SiC), gallium phosphide (GaP), and zinc oxide (ZnO), gallium nitride (GaN), germanium (Ge) or silicon (Si). In addition to the above-mentioned conductive material, the semiconductor device 3 may also include insulating materials such as sapphire. In some embodiments, such as semiconductor devices 2, 3, and 5, the base 70 is a bonding substrate rather than a growth substrate, which is bonded to the epitaxial structure thereon through the adhesive layers A and A″, as shown in FIGS. 5. 6 and 8.

The first electrode structure 60 and the second electrode structure 80 electrically connect to an external power source. The materials of the first electrode structure 60 and the second electrode structure 80 may be the same or different, such as including metal oxide, metal or alloy respectively. The metal oxide includes indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), gallium phosphide (GaP), indium cerium oxide (ICO), indium tungsten oxide (IWO), indium titanium oxide (ITiO), indium zinc oxide (IZO), indium gallium oxide (IGO), gallium aluminum zinc oxide (GAZO) or a combination of the above materials. The metal includes germanium (Ge), beryllium (Be), zinc (Zn), gold (Au), platinum (Pt), titanium (Ti), aluminum (Al), nickel (Ni), tin (Sn) or copper (Cu). The alloy may include at least two metals selected from the above metals, such as germanium gold nickel (GeAuNi), beryllium gold (BeAu), germanium gold (GeAu) or zinc gold (ZnAu).

The adhesive layer A connects the base 70 and the photonics crystal structure 20. The adhesive layer A′ connects the base 70 and the first semiconductor structure 10. The adhesive layer A, A′ can be a single layer or multiple layers (not shown). In some embodiments, as shown in FIGS. 5 and 8, the material of adhesive layer A may include conductive material. The conductive materials may be metal, alloy or metal oxide. The metal may include o germanium (Ge), beryllium (Be), zinc (Zn), gold (Au), platinum (Pt), titanium (Ti), aluminum (Al), nickel (Ni), tin (Sn) or copper (Cu). The alloy may include at least two metals selected from the above. The metal oxide include indium tin oxide (ITO), indium oxide (InO), tin oxide (SnO), cadmium tin oxide (CTO), antimony tin oxide (ATO), aluminum oxide Zinc (AZO), zinc tin oxide (ZTO), gallium zinc oxide (GZO), zinc oxide (ZnO), gallium phosphide (GaP), indium cerium oxide (ICO), indium tungsten oxide (IWO), indium titanium oxide (ITiO), indium zinc oxide (IZO), indium gallium oxide (IGO), gallium aluminum zinc oxide (GAZO) or a combination of the above materials. In another embodiment, as shown in FIG. 6, the material of adhesive layer A′ may include transparent insulating material, such as titanium oxide (TiO₂), niobium oxide (Nb₂O₅), silicon oxide (SiO₂), aluminum oxide (Al₂O₃), silicon nitride (SiNₓ), or BCB.

In the embodiment, the protective layer 90 and the blocking structure C can be a single-layer, double-layer or multi-layer structure. In addition, the protective layer 90 and the blocking structure C may include dielectric material, such as silicon oxide (SiO₂), silicon nitride (SiNₓ), niobium oxide (Nb₂O₅), titanium oxide (TiO₂), magnesium fluoride (MgF₂) or combinations thereof.

The reflective layer R can reflect the light emitted by the active structure 30 so that the light emits out of the semiconductor devices 2 and 5 in the direction toward the first semiconductor structure 10. The reflective layer R can be conductive and can optionally include semiconductor material, metal or alloy. The semiconductor material may include III-V semiconductor material, such as a binary, ternary or quaternary III-V semiconductor material. Metal includes copper (Cu), aluminum (Al), tin (Sn), gold (Au) or silver (Ag). The alloy may include at least two metals selected from above. In the embodiment, the material of the reflective layer R is metal.

The first thickness T1, the second thickness T2, the third thickness T3, the depth D, the first distance D1, the second distance D2, and the third distance D3 are parallel to the epitaxial stacking direction, such as the direction along Z axis in the drawing. The width w, the first width w1, the second width w2, and the third width w3 are perpendicular to the epitaxial stacking direction, such as the direction along X axis in the drawing.

Specifically, the epitaxial structure and the semiconductor device can be applied to products in the fields of lighting, medical care, display, communication, sensing, or power supply systems. Such as lamps, Monitors, mobile phones, tablets, car dashboards, TVs, computers, wearable devices (such as watches, bracelets or necklaces), traffic signals, outdoor displays, or medical equipment.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a first semiconductor structure;
a second semiconductor structure on the first semiconductor structure and comprising a first aluminum content;
a plurality of voids in the second semiconductor structure;
an active structure between the first semiconductor structure and the second semiconductor structure; and
a third semiconductor structure between the active structure and the second semiconductor structure, and comprising a second aluminum content;
wherein the first aluminum content is greater than the second aluminum content.

2. The semiconductor device of claim 1, wherein the third semiconductor structure comprises InP.

3. The semiconductor device of claim 1, wherein one of the plurality of voids comprises a depth between 200 nm and 650 nm.

4. The semiconductor device of claim 1, wherein one of the plurality of voids penetrates a part of the third semiconductor structure.

5. The semiconductor device of claim 4, wherein the active structure comprises a first surface facing one of the plurality of voids, and a distance between the first surface and the void is between 10 nm and 150 nm.

6. The semiconductor device of claim 1, further comprising a conductive layer and a contact structure between the second semiconductor structure and the conductive layer.

7. The semiconductor device of claim 6, wherein the active structure is separated from the conductive layer by a first distance, and the first semiconductor structure comprises a thickness different from first distance.

8. The semiconductor device of claim 1, further comprising a base and an adhesive layer between the base and the second semiconductor structure.

9. The semiconductor device of claim 8, wherein the adhesive layer connects the base and the first semiconductor structure, and the adhesive layer comprises insulating material.

10. The semiconductor device of claim 8, further comprising a reflective layer between the adhesive layer and the second semiconductor structure, and the adhesive layer electrically connects to the reflective layer.

11. The semiconductor device of claim 10, further comprising a plurality of blocking structures between the reflective layer and the second semiconductor structure.

12. The semiconductor device of claim 1, wherein the semiconductor device emits a light with a wavelength between 1000 nm and 2000 nm.

13. The semiconductor device of claim 1, further comprising a fourth semiconductor structure between the second semiconductor structure and the active structure.

14. The semiconductor device of claim 13, wherein the second semiconductor structure and the fourth semiconductor structure comprise the same material.

15. The semiconductor device of claim 1, wherein the second semiconductor structure comprises a first etching rate and the third semiconductor structure comprises a second etching rate, and the first etching rate is 1.5 to 10 times greater than the second etching rate.

16. The semiconductor device of claim 1, further comprising a first electrode structure and a second electrode structure, and the second semiconductor structure located between the first electrode structure and the second electrode structure.

17. The semiconductor device of claim 1, further comprises a first electrode structure and a second electrode structure arranged on the same side of the first semiconductor structure.

18. The semiconductor device of claim 1, wherein the second semiconductor structure comprises a filling factor between 0.1 and 0.25.

19. The semiconductor device of claim 1, wherein the plurality of voids is devoid of penetrating the fourth semiconductor structure.

20. The semiconductor device of claim 1, wherein a width of one of the plurality of voids increases in the direction away from the active structure.
